(19) United States
(12) Patent Application Publication
(10) Pub. No.: US 2008/0067666 A1
(43) Pub. Date: Mar. 20, 2008

(54) CIRCUIT BOARD STRUCTURE WITH EMBEDDED SEMICONDUCTOR CHIP AND METHOD FOR FABRICATING THE SAME

(75) Inventor: Shih-Ping HSU, Hsin-chu (TW)

Correspondence Address: SAWYER LAW GROUP LLP, P O BOX 51418, PALO ALTO, CA, 94303, US

(73) Assignee: PHOENIX PRECISION TECHNOLOGY CORPORATION, Hsin-chu (TW)

(21) Appl. No.: 11/771,345

(22) Filed: Jun. 29, 2007

(30) Foreign Application Priority Data
Sep. 19, 2006 (TW) 095134529

(51) Int. Cl. H01L 23/48; H01L 21/4763

(52) U.S. Cl. 257/700; 438/106; 257/E23.01; 257/E21.495

(57) ABSTRACT

A circuit board structure having an embedded semiconductor chip and a method for fabricating the same are disclosed. The circuit board structure includes: a carrier board formed with at least one through hole; a semiconductor chip received in the through hole of the carrier board, the semiconductor chip having an active surface and a non-active surface, wherein the active surface is provided with a plurality of electrode pads; a dielectric layer formed on surfaces of the carrier board and the semiconductor chip and formed with a plurality of openings for exposing the electrode pads of the semiconductor chip; and a composite circuit layer formed on the dielectric layer, including a thinned metal layer, conductive layer, and electroplated metal layer, and electrically connected to the electrode pads by conductive structures formed in the openings of the dielectric layer. Strong bonding provided by the composite circuit layer formed on the dielectric layer thus desirably reduces the warpage problem resulted from thermal effect.

### BACKGROUND OF THE INVENTION

1. Field of the Invention

The present invention relates to circuit board structures, and more particularly, to a circuit board structure with an embedded semiconductor chip and a method for fabricating the same.

2. Description of the Prior Art

Flip chip package technology was introduced into the industry by IBM in the early 1960s. Unlike wire bonding technology, flip chip package technology involves establishing an electrical connection between a semiconductor chip and a substrate via solder bumps instead of gold wires. Flip chip package technology is advantageous because it is capable of increasing package density, reducing the size of the package without the need of using long gold wires, and thus enables better electrical performance of the packaged components.

In recent years, owing to an increasing demand towards high-densitiy, hight-speed and low-cost semiconductor chips, as well as the demand of miniaturization and high integration for electronic products nowadays, semiconductor manufacturers have developed a package where a chip is embedded in an opening of a circuit board having a circuit build-up structure. A method for fabricating this circuit build-up structure is illustrated in FIGS. 1A to 1C.

Referring to FIG. 1A, the method comprises providing a carrier board 11 formed with a through hole 110 for receiving a semiconductor chip 12. The semiconductor chip 12 has an active surface 12a and a non-active surface 12b opposite to the active surface 12a, and the active surface 12a is provided with a plurality of electrode pads 121.

Referring to FIG. 1B, the method further comprises forming a dielectric layer 13 on the carrier board 11 and the active surface 12a of the semiconductor chip 12. The dielectric layer 13 is formed with a plurality of openings 130 for exposing the electrode pads 121 of the semiconductor chip 12.

Referring to FIG. 1C, the method further comprises forming a circuit layer 14 on the dielectric layer 13, and conductive structures 141 in the openings 130 of the dielectric layer 13. The conductive structures 141 are electrically connected to the electrode pads 121 of the semiconductor chip 12. The circuit layer 14 is fabricated by a well-known semi-additive process and therefore is not described in detail herein. All the steps of the method can be repeated, so as to form a multi-layered circuit, and then the semiconductor chip 12 is packaged in the carrier board 11 and electrically connected with the other electronic components thereon.

However, the difference between the carrier board 11, dielectric layer 13, and circuit layer 14 in terms of the coefficient of thermal expansion (CTE) is so great that warpage is likely to occur due to temperature variation of the process, thus compromising product quality.

Accordingly, an issue facing the semiconductor industry nowadays and calling for urgent solution involves solving the CTE-related reliability problem in a circuit build-up process of fabricating a circuit board structure with an embedded semiconductor chip.

### SUMMARY OF THE INVENTION

In light of the aforesaid drawbacks of the prior art, it is a primary objective of the present invention to disclose a circuit board structure with an embedded semiconductor chip and a method for fabricating the same, such that the bonding strength between the composite circuit layer formed by a thinned metal layer, conductive layer, and electroplated metal layer and the dielectric layer is enhanced via the resin coated element comprising a dielectric layer and a metal layer formed thereon, composite circuit layer and thus warpage is unlikely to occur to the circuit board.

In order to achieve the above and other objectives, the present invention discloses a method for fabricating a circuit board structure having an embedded semiconductor chip. The method comprises the steps of: providing a carrier board formed with at least one through hole penetrating the carrier board; receiving at least one semiconductor chip having an active surface on which a plurality of electrode pads are disposed and an opposing non-active surface in the through hole of the carrier board; laminating a resin coated element on the carrier board and the active surface of the semiconductor chip, in which the resin coated element is made of a dielectric layer and a metal layer formed thereon; performing a thinning process on a surface of the metal layer of the resin coated element so as to turn the metal layer into a thinned metal layer; forming in the resin coated element a plurality of openings for exposing the electrode pads of the semiconductor chip; forming a conductive layer on the thinned metal layer of the resin coated element and in the openings of the resin coated element; forming on the conductive layer a resist, forming, by a patterning process, in the resist a plurality of openings for exposing a portion of the conductive layer; forming an electroplated metal layer on the conductive layer in the openings of the resist; and removing the resist and a resist-covered portion of the conductive layer and thinned metal layer thereunder so as to expose the dielectric layer of the resin coated element and form a composite circuit layer comprising the electroplated metal layer, conductive layer, and thinned metal layer, forming in the openings of the dielectric layer of the resin coated element conductive structures for electrically connecting the composite circuit layer to the electrode pads of the semiconductor chip.

The resin coated element is formed by laminating a metal layer on the surface of a dielectric layer, or bonding a metal layer on the surface of a dielectric layer via an adhesive layer. The metal layer of the resin coated element is a copper foil. The dielectric layer of the resin coated element is a prepreg. The thinning process is performed, physically or chemically, on the surface of the metal layer of the resin coated element so as to turn the metal layer into the thinned metal layer.

The method further comprises the steps of: forming a circuit build-up structure on the dielectric layer of the resin coated element and the composite circuit layer, wherein the circuit build-up structure is comprised of a plurality of dielectric layers of resin coated elements and a plurality of composite circuit layers. Furthermore, a plurality of conductive structures for electrical connection with the semiconductor chip is formed on the outer surface of the circuit build-up structure. The circuit build-up structure comprises at least one dielectric layer, at least one composite circuit layer superimposed on the dielectric layer, and conductive structures formed in the dielectric layer A solder mask layer is formed on the circuit build-up structure, with a plurality of openings for exposing the electrically connecting pads.

The method further comprises the steps of: forming a circuit build-up structure on the dielectric layer of the resin coated element and the composite circuit layer, wherein the circuit build-up structure comprises a plurality of dielectric layers and a plurality of circuit layers, each of which is made up of a conductive layer and an electroplated metal layer. More specifically, the circuit build-up structure comprises atileast one dielectric layer, at least one circuit layer superimposed on the dielectric layer, and conductive structures formed in the dielectric layer to be electrically connected with the circuit layer, and a plurality of electrically connecting pads formed on the outer surface of the circuit build-up structure. A solder mask layer is formed on the circuit build-up structure, with a plurality of openings for exposing the electrically connecting pads.

Referring to the method, the present invention discloses a circuit board structure having an embedded semiconductor chip. The circuit board structure comprises: a carrier board having at least one through hole penetrating the carrier board; a semiconductor chip having an active surface on which a plurality of electrode pads are disposed and an opposing non-active surface received in the through hole of the carrier board; a dielectric layer formed on the carrier board and the semiconductor chip and formed with a plurality of openings for exposing the electrode pads of the semiconductor chip; and a composite circuit layer formed on the dielectric layer, comprised of a thinned metal layer, a conductive layer, and an electroplated metal layer from bottom to top, and electrically connected to the electrode pads of the semiconductor chip via conductive structures formed in the openings of the dielectric layer.

The circuit board structure further comprises a circuit build-up structure formed on the dielectric layer and the composite circuit layer. The circuit build-up structure comprises a plurality of dielectric layers of resin coated elements and a plurality of circuit layers. Alternatively, the circuit build-up structure comprises a plurality of dielectric layers and a plurality of circuit layers. The circuit build-up structure is provided with conductive structures for electrical connection with the composite circuit layer. A plurality of electrically connecting pads is formed on the outer surface of the circuit build-up structure. The circuit build-up structure comprises at least one dielectric layer, at least one composite circuit layer superimposed on the dielectric layer, and the conductive structures formed in the dielectric layer. Formed on the circuit build-up structure is a solder mask, and formed in the solder mask are a plurality of openings for exposing the electrically connecting pads.

The circuit board structure further comprises a circuit build-up structure formed on the dielectric layer and the composite circuit layer. The circuit build-up structure comprises a plurality of dielectric layers and a plurality of circuit layers. Each of the circuit layers comprises a conductive layer and an electroplated metal layer. The circuit build-up structure comprises at least one dielectric layer, at least one circuit layer superimposed on the dielectric layer, and conductive structures formed in the dielectric layer. The conductive structures are electrically connected to the composite circuit layer. A plurality of electrically connecting pads is formed on the outer surface of the circuit build-up structure. The circuit board structure further comprises a solder mask formed on the circuit build-up structure. Formed in the solder mask is a plurality of openings for exposing the electrically connecting pads.

The resin coated element of the present invention is formed by laminating the coarse surface of a metal layer, preferably made by a copper foil, on the dielectric layer, made by a prepreg. Alternatively, an adhesive layer is used to tightly bond the coarse surface of the copper foil and the prepreg together. With a glass fiber-reinforced prepreg functioning as the dielectric layer, problems such as warpage and variation of dimensions are effectively reduced. In the present invention, owing to the combination of the metal layer and dielectric layer, the bonding strength between the composite circuit layer and dielectric layer formed by a thinned metal layer, conductive layer, and electroplated metal layer increases, and thus warpage is unlikely to occur to the circuit board.

### BRIEF DESCRIPTION OF THE DRAWINGS

FIGS. 1A to 1C (PRIOR ART) are cross-sectional views showing a method for fabricating a circuit board structure having an embedded semiconductor chip according to the prior art;

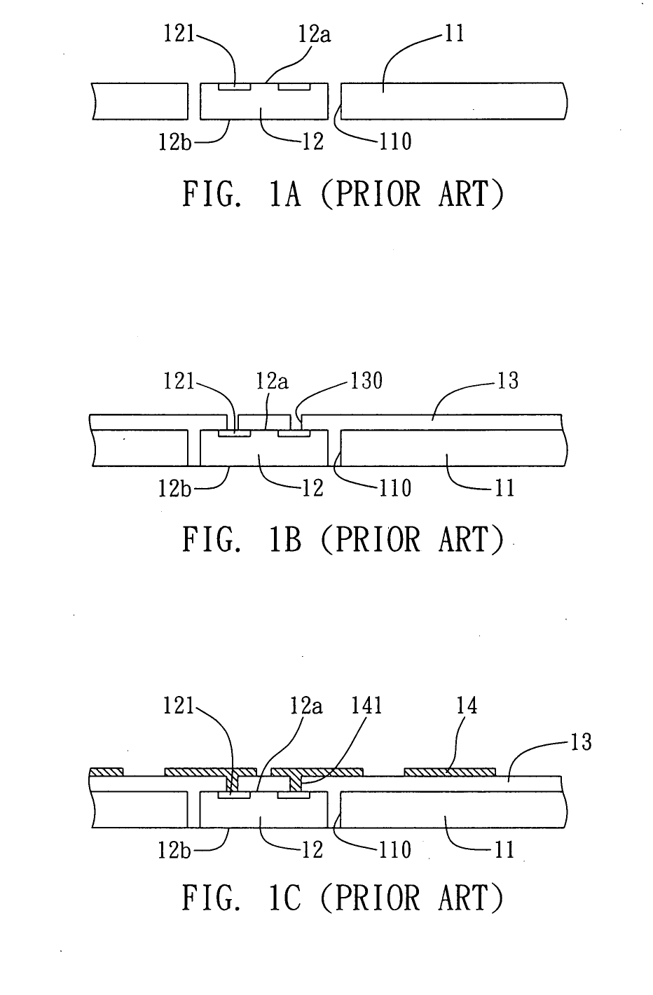

FIGS. 2A to 2G are cross-sectional views showing a circuit board structure having an embedded semiconductor chip and a method for fabricating the same in accordance with the present invention;

FIG. 2A′ is a cross-sectional view showing another embodiment of a circuit board structure having an embedded semiconductor chip and a method for fabricating the same shown in FIG. 2A in accordance with the present invention;

FIG. 2B′ is a cross-sectional view showing another embodiment of a circuit board structure having an embedded semiconductor chip and a method for fabricating the same shown in FIG. 2B in accordance with the present invention;

FIGS. 3A and 3B are cross-sectional views showing how to build up a circuit build-up structure with a circuit board structure of the present invention; and

FIG. 4 is a cross-sectional view showing another embodiment of building up a circuit build-up structure with a circuit board structure of the present invention.

### DETAILED DESCRIPTION OF THE PREFERRED EMBODIMENTS

The following specific embodiments are provided to illustrate the present invention. Persons skilled in the art can readily gain an insight into other advantages and features of the present invention based on the contents disclosed in this specification.

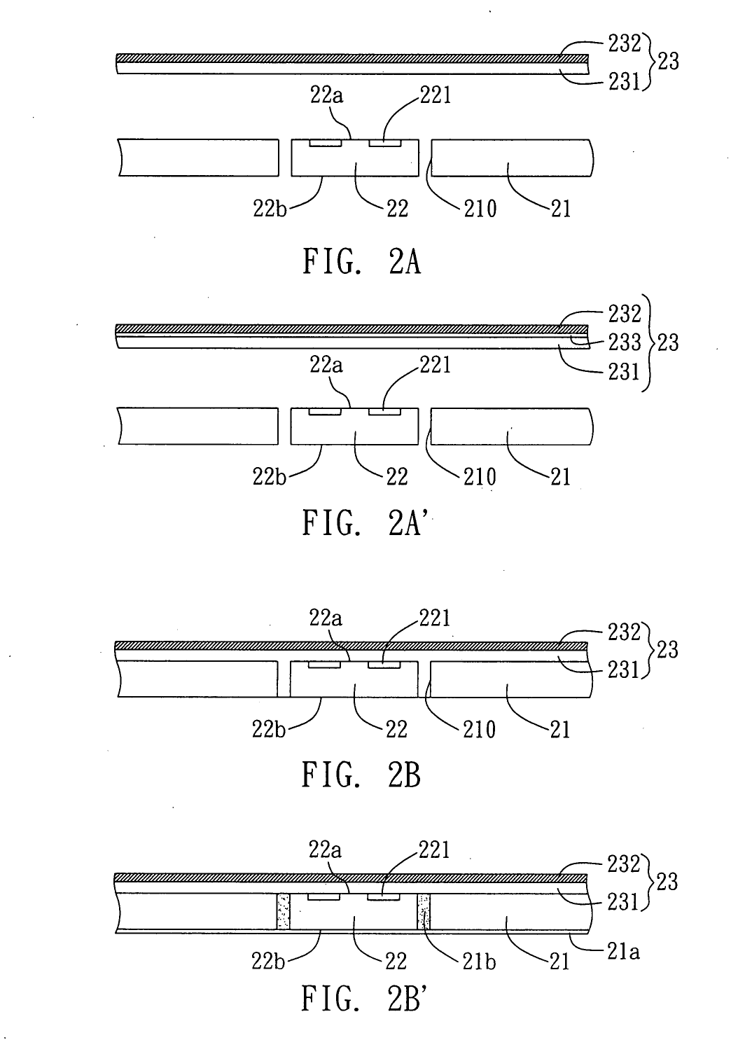

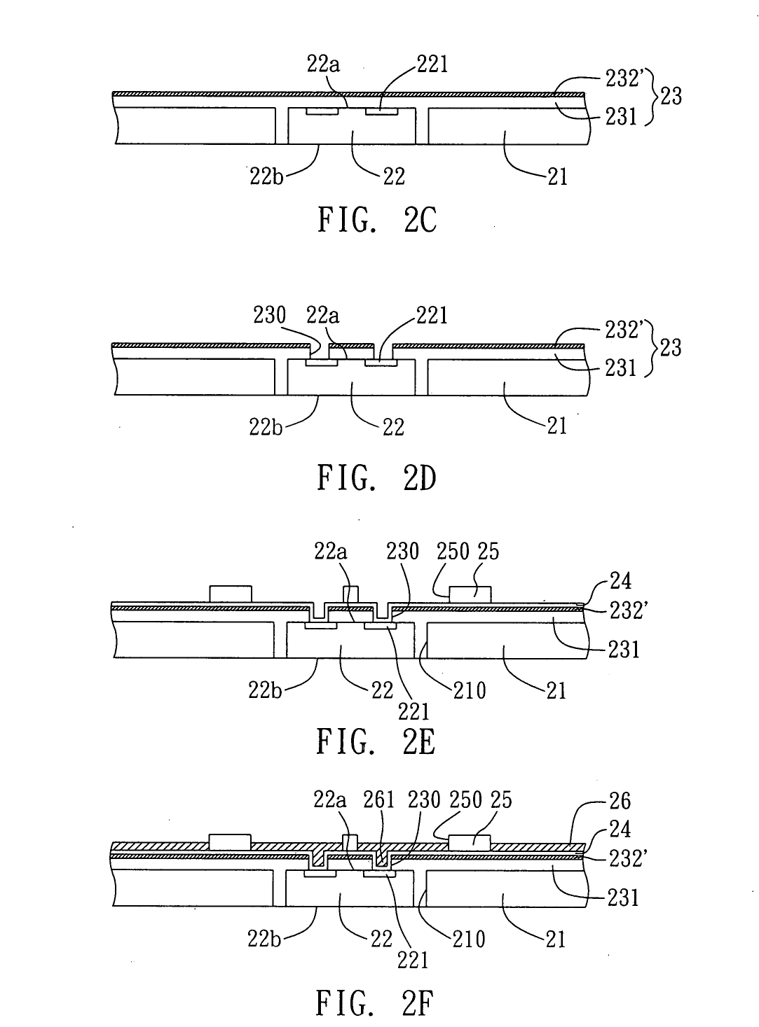

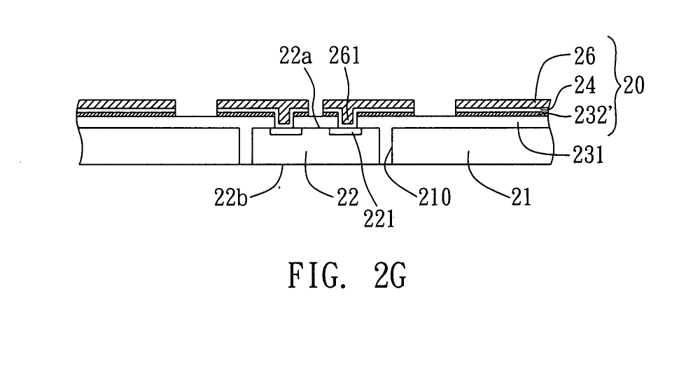

Referring to FIGS. 2A to 2G, cross-sectional views of a circuit board structure having an embedded semiconductor chip and a method for fabricating the same in accordance with the present invention are provided.

As shown in FIG. 2A, the method comprises: forming in a carrier board 21 at least one through hole 210 penetrating the carrier board 21, wherein at least one semiconductor chip 22 having an active surface 22a on which a plurality of electrode pads 221 are disposed and a non-active surface 22b opposite to the active surface 22a is received in the through hole 210; providing a resin coated element 23 comprising a dielectric layer 231 and a metal layer 232 formed thereon, wherein the metal layer 232 has a coarse surface and thereby is better coupled to and integrated with the dielectric layer 231. The metal layer 232 is a copper foil, and the dielectric layer 231 is a prepreg. Referring to FIG. 2A′, alternatively, the resin coated element 23 comprises the dielectric layer 231, the metal layer 232, and an adhesive layer 233 provided between the dielectric layer 231 and the metal layer 232 to bond the dielectric layer 231 and the metal layer 232 together. The metal layer 232 is preferably a copper foil having a coarse surface, and, through the coarse surface, the copper foil is bonded to a prepreg by lamination; alternatively, the adhesive layer 233 is used to tightly bond the copper foil to the prepreg through the coarse surface of the copper foil. As a result, a preferable bonding can be achieved and the problems such as warpage and variation in dimensions of a circuit board can be minimized with the use of a glass fiber-reinforced prepreg.

As shown in FIG. 2B, the method further comprises: laminating the dielectric layer 231 of the resin coated element 23 to the carrier board 21 and the active surface 22a of the semiconductor chip 22; and extrusion filling a gap between the semiconductor chip 22 and the through hole 210 with the dielectric layer 231, so as to secure in position the semiconductor chip 22 to the through hole 210.

As shown in FIG. 2B′, alternatively the method further comprises: laminating a release film 21a to the bottom surface of the carrier board 21; positioning the semiconductor chip 22 in the through hole 210; filling the gap between the semiconductor chip 22 and the through hole 210 with an adhesive material 21b, so as to secure in position the semiconductor chip 22 to the through hole 210; and laminating the dielectric layer 231 of the resin coated element 23 to the carrier board 21 and the active surface 22a of the semiconductor chip 22.

In this step could also laminating a release film 21a to the bottom surface of the carrier board 21; positioning the semiconductor chip 22 in the through hole 210 wherein the active surface 22a attach to the release film 21a; filling the gap between the semiconductor chip 22 and the through hole 210 with an adhesive material 21b, so as to secure in position the semiconductor chip 22 to the through hole 210; removing the release film 21a; and laminating the dielectric layer 231 of the resin coated element 23 to the carrier board 21 and the active surface 22a of the semiconductor chip 22.

Illustration of a circuit board structure having an embedded semiconductor chip and a fabrication method thereof in accordance with the present invention is hereinafter based on FIG. 2B for the sake of brevity.

As shown in FIG. 2C, the method further comprises performing a thinning process on the surface of the metal layer 232 of the resin coated element 23 physically or chemically to turn the metal layer 232 into a thinned metal layer 232′.

As shown in FIG. 2D, the method further comprises forming in the resin coated element 23 a plurality of openings 230 for exposing the electrode pads 221 of the semiconductor chip 22.

As shown in FIG. 2E, the method further comprises: forming on the surface of the thinned metal layer 232′ of the resin coated element 23 and in the openings 230 a conductive layer 24 electrically connected to the electrode pads 221 of the semiconductor chip 22; and forming a resist 25 on the conductive layer 24, wherein openings 250 for exposing a portion of the conductive layer 24 are formed in the resist 25 by a patterning process (for example, exposure and development).

As shown in FIG. 2F, the method further comprises: forming, with the conductive layer 24 functioning as a path of electrical conduction, an electroplated metal layer 26 on the conductive layer 24 in the openings 250 of the resist 25 and conductive structures 261 in the openings 230 of the dielectric layer 231.

As shown in FIG. 2G, the method further comprises removing the resist 25 and a resist-covered portion of the conductive layer 24 and thinned metal layer 232′ thereunder so as to form a composite circuit layer 20 comprising the electroplated metal layer 26, conductive layer 24, and thinned metal layer 232′, wherein the composite circuit layer 20 is electrically connected to the electrode pads 221 of the semiconductor chip 22 via the conductive structures 261.

Inasmuch as the conductive layer 24 and electroplated metal layer 26 of the composite circuit layer 20 are formed on the thinned metal layer 232′ of the resin coated element 23, CTE-related warpage problem is minimized because of the resin coated element 23 provided, and thus the product quality is assured.

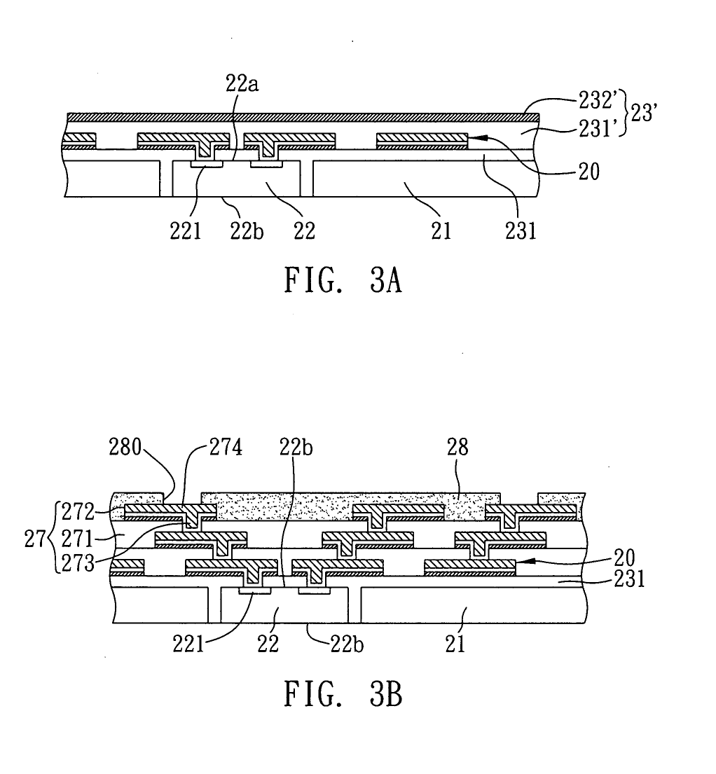

Referring to FIGS. 3A and 3B, the method further comprises laminating another resin coated element 23′ onto the composite circuit layer 20 and an exposed portion of the dielectric layer 231 as shown in FIG. 3A; and forming another composite circuit layer by performing the aforesaid process on the resin coated element 23′, thereby resulting in a circuit build-up structure 27 comprising the plurality of dielectric layers 231 of resin coated elements 23′ and the plurality of composite circuit layers 20 as shown in FIG. 3B. The circuit build-up structure 27 comprises at least one dielectric layer 271, a circuit layer 272 superimposed on the dielectric layer 271, and conductive structures 273 formed in the dielectric layer 271. The conductive structures 273 are electrically connected to the composite circuit layers 20. Then, the method further comprises: forming a plurality of electrically connecting pads 274 on an outer surface of the circuit build-up structure 27; forming a solder mask 28 on the circuit build-up structure 27; and forming in the solder mask 28 a plurality of openings 280 for exposing the electrically connecting pads 274.

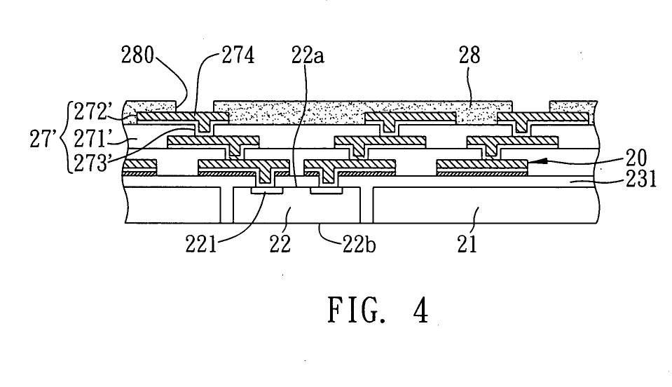

Referring to FIG. 4, the method further comprises forming a circuit build-up structure 27′ on the dielectric layers 231 and the composite circuit layers 20. Forming the circuit build-up structure 27′ comprises: forming a dielectric layer 271′ on the dielectric layers 231 of the resin coated elements 23 and the composite circuit layers 20, forming a circuit layer 272′ on the dielectric layer 271′, and forming at least one conductive structure 273′ in the dielectric layer 271′, wherein the circuit layer 272′ comprises a conductive layer and an electroplated metal layer. The aforesaid circuit build-up technology is known to persons of skill in the art and therefore is not described herein in detail. A plurality of electrically connecting pads 274′ and a solder mask 28 are formed on the surface of the circuit build-up structure 27′. Formed in the solder mask 28 are a plurality of openings 280 for exposing the electrically connecting pads 274′.

The resin coated element of the present invention is formed by laminating the coarse surface of a metal layer, preferably made by a copper foil, on the dielectric layer, made by a prepreg. Alternatively, an adhesive layer is used to tightly bond the coarse surface of the copper foil and the prepreg together. With a glass fiber-reinforced prepreg functioning as the dielectric layer, problems such as warpage and variation of dimensions are effectively reduced. In the present invention, owing to the combination of the metal layer and dielectric layer, the bonding strength between the composite circuit layer and dielectric layer formed by a thinned metal layer, conductive layer, and electroplated metal layer increases, and thus warpage is unlikely to occur to the circuit board.

The aforesaid embodiments merely serve as the preferred embodiments of the present invention. The aforesaid embodiments should not be construed as to limit the scope of the present invention in any way. Hence, any other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A circuit board structure having an embedded semiconductor chip, the circuit board structure comprising:
a carrier board having at least one through hole penetrating the carrier board;
a semiconductor chip received in the through hole of the carrier board and provided with an active surface and a non-active surface, the active surface having a plurality of electrode pads;
a dielectric layer formed on the carrier board and the semiconductor chip and formed with a plurality of openings for exposing the electrode pads of the semiconductor chip; and
a composite circuit layer formed on the dielectric layer, comprised of a thinned metal layer, a conductive layer, and an electroplated metal layer from bottom to top, and electrically connected to the electrode pads of the semiconductor chip via conductive structures formed in the openings of the dielectric layer.

2. The circuit board structure of claim 1, further comprising a circuit build-up structure formed on the dielectric layer and the composite circuit layer.

3. The circuit board structure of claim 2, wherein the circuit build-up structure comprises at least one dielectric layer and at least one composite circuit layer.

4. The circuit board structure of claim 3, wherein the circuit build-up structure is provided with conductive structures for establishing an electrical connection with the composite circuit layer formed on the dielectric layer, and a plurality of electrically connecting pads formed on the outer surface of the circuit build-up structure.

5. The circuit board structure of claim 4, further comprising a solder mask formed on the circuit build-up structure and formed with a plurality of openings for exposing the electrically connecting pads.

6. The circuit board structure of claim 3, wherein the circuit build-up structure comprises at least one dielectric layer, at least one composite circuit layer superimposed on the dielectric layer, and the conductive structures formed in the dielectric layer.

7. The circuit board structure of claim 2, wherein the circuit build-up structure comprises a dielectric layer and a circuit layer comprising an electroplated metal layer and a conductive layer.

8. The circuit board structure of claim 7, wherein the circuit build-up structure comprises conductive structures for establishing an electrical connection with the composite circuit layer formed on the dielectric layer, and a plurality of electrically connecting pads formed on the outer surface of the circuit build-up structure.

9. The circuit board structure of claim 8, further comprising a solder mask formed on the circuit build-up structure and formed with a plurality of openings for exposing the electrically connecting pads.

10. The circuit board structure of claim 7, wherein the circuit build-up structure comprises at least one dielectric layer, at least one circuit layer superimposed on the dielectric layer, and conductive structures formed in the dielectric layer.

11. The circuit board structure of claim 1, wherein the dielectric layer is a prepreg.

12. A method for fabricating a circuit board structure having an embedded semiconductor chip, the method comprising the steps of:
providing a carrier board formed with at least one through hole penetrating the carrier board;
receiving at least one semiconductor chip in the through hole of the carrier board, the semiconductor chip having an active surface and a non-active surface opposite to the active surface, the active surface being provided with a plurality of electrode pads;
laminating a resin coated element on the carrier board and the active surface of the semiconductor chip, the resin coated element comprising a dielectric layer and a metal layer formed thereon;
performing a thinning process on the metal layer of the resin coated element so as to turn the metal layer into a thinned metal layer;
forming in the resin coated element a plurality of openings for exposing the electrode pads of the semiconductor chip;
forming a conductive layer on the thinned metal layer of the resin coated element and in the openings of the resin coated element;
forming on the conductive layer a resist, forming, by a patterning process, in the resist a plurality of openings for exposing a portion of the conductive layer;
forming an electroplated metal layer on the conductive layer in the openings of the resist; and
removing the resist and a resist-covered portion of the conductive layer and thinned metal layer thereunder so as to expose the dielectric layer of the resin coated element and form a composite circuit layer comprising the electroplated metal layer, conductive layer, and thinned metal layer, forming in the openings of the dielectric layer of the resin coated element conductive structures for electrically connecting the composite circuit layer to the electrode pads of the semiconductor chip.

13. The method of claim 12, further comprising forming a circuit build-up structure on the dielectric layer and the composite circuit layer.

14. The method of claim 12, wherein the circuit build-up structure comprises at least one dielectric layer and at least one composite circuit layer.

15. The method of claim 14, wherein the circuit build-up structure is provided with conductive structures for establishing an electrical connection with the composite circuit layer formed on the dielectric layer, and a plurality of electrically connecting pads formed on the outer surface of the circuit build-up structure.

16. The method of claim 15, further comprising a solder mask formed on the circuit build-up structure and formed with a plurality of openings for exposing the electrically connecting pads.

17. The method of claim 14, wherein the circuit build-up structure comprises at least one dielectric layer, at least one composite circuit layer superimposed on the dielectric layer, and conductive structures formed in the dielectric layer.

18. The method of claim 13, wherein the circuit build-up structure comprises the dielectric layer and a circuit layer comprising an electroplated metal layer and a conductive layer.

19. The method of claim 18, wherein the circuit build-up structure comprises conductive structures for electrical connection with the composite circuit layer formed on the dielectric layer, and a plurality of electrically connecting pads formed on the outer surface of the circuit build-up structure.

20. The method of claim 19, further comprising a solder mask formed on the circuit build-up structure and formed with a plurality of openings for exposing the electrically connecting pads.

21. The method of claim 18, wherein the circuit build-up structure comprises at least one dielectric layer, at least one circuit layer superimposed on the dielectric layer, and conductive structures formed in the dielectric layer.
